(19) United States
(12) Patent Application Publication
(10) Pub. No.: US 2004/0155286 A1
(43) Pub. Date: Aug. 12, 2004

(54) Semiconductor device with enhanced drain and gate

(76) Inventor: Ali Salih, Mesa, AZ (US)

Correspondence Address: ALI SALIH, 2953 E. HACKAMORE ST., MESA, AZ, 85213, US

(21) Appl. No.: 10/464,681

(22) Filed: Jun. 17, 2003

Related U.S. Application Data
(60) Provisional application No. 60/390,495, filed on Jun. 21, 2002.
(60) Provisional application No. 60/390,474, filed on Jun. 21, 2002.

(51) Int. Cl. H01L 29/76

(52) U.S. Cl. 257/328

(57) ABSTRACT

A semiconductor device has enhanced drain and gate structures where a high conductivity region 12 is added to enhance current conduction, and further region 23 with opposite polarity is included to improve breakdown voltage. Regions 12 and 23 are disposed in the epitaxial layer portion of the drain. A thicker insulator is also formed in the gate-to-drain region. Furthermore, a gate structure with a trench is formed in a portion of the drain region, having lateral and vertical gate electrode elements and thick gate to drain insulator. Gate capacitance and resistance are improved by the gate and drain structures of this invention.

### CROSS-REFERENCE TO RELATED APPLICATIONS

This application is a corresponding non-provisional patent application, and claims priority to:

Provisional Patent application No. 60/390,495, filed by Ali Salih on Jun. 21, 2002 titled “Transistor with Enhanced Drain and Gate Structures”; and

Provisional Patent application No. 60/390,474, filed by Ali Salih on Jun. 21, 2002 titled “Semiconductor Device Structure”.

### REFERENCES CITED

### U.S. Patent Documents

| | | | | |
|---|---|---|---|---|
| 4,344,081 | Aug. 10, 1982 | Pao et. al | . . . | 357/43 |
| 4,593,302, | Jun. 3, 1986 | Lidow et al | . . . | 357/23.4 |
| 4,767,722 | Aug. 30, 1988 | Blanchard | . . . | 437/41 |
| 6,420,756 | Mar. 12, 2001 | Salih | . . . | 357/330 |

### BACKGROUND OF THE INVENTION

The present invention relates in general to semiconductor devices, and more particularly, to power field effect transistors.

Power transistors are typically designed using planar or trench cells which are paralleled at high density on a semiconductor chip to conduct high current and power. U.S. Pat. No. 4,344,081, issued to Pao et al. on Aug. 10, 1982 shows an example of trench design, and U.S. Pat. No. 4,593,302, issued to Lidow et al. on Jun. 3, 1986 is an example of planar structure. The space of the drain region of a transistor outlined by the body region and drain contact having a relatively low carrier concentration is referred to as the drift region where the carrier concentration is controlled to obtain required breakdown voltage. The carrier concentration, or doping level, of the drift region portion of the drain has a significant impact on the drain-to-source on-resistance of the device and low carrier concentration causes the on-resistance of the power field effect transistor (FET) to be undesirably high. Moreover, the thickness of gate-to-drain insulator is typically the same as that of gate-to-source insulator, which is maintained at a small thickness to allow low threshold voltage. Thin gate-to-drain insulator gives rise to large gate-to-drain capacitance. The gate resistance provided by conventional techniques is also undesirably high due to the small cross-sectional area of gate electrode. High gate capacitance and resistance amount to high gate delay time and slow switching speed, and necessitate high gate drive current.

On-resistance and gate parasitics (resistance, capacitance) of power FET's determine the conduction and switching losses, respectively. For power conversion applications poor conduction and gate switching performance results in degradation of efficiency. Prior solutions typically attempt to engineer the tradeoffs between on-resistance and gate parasitics. Hence, there is a need for power transistors where both conduction and switching efficiencies are improved by reducing on-resistance, and gate resistance and capacitance.

### BRIEF DESCRIPTION OF THE FIGURES

The objects and advantages of the innovation will become apparent to those skilled in the art from the following detailed description thereof, taken in conjunction with the drawings, in which:

FIG. 1 is a vertical sectional view of the main portion of a transistor cell constructed in accordance with teachings of the instant invention;

FIG. 2 is a vertical sectional view of an alternate embodiment of the invention with an alternate gate structure;

FIG. 3 is a vertical sectional view of a preferred embodiment of the invention;

FIG. 4 is a vertical sectional view of an alternate embodiment of the invention;

FIG. 5 is a vertical sectional view of an alternate embodiment of the drain region of a planar transistor;

FIG. 6 is a vertical sectional view of an alternate embodiment including a planar-trench structure in accordance with the present invention; and

FIG. 7 is a vertical sectional view of an alternate embodiment of the invention, with enhanced gate and drain structures.

### DETAILED DESCRIPTION OF THE FIGURES

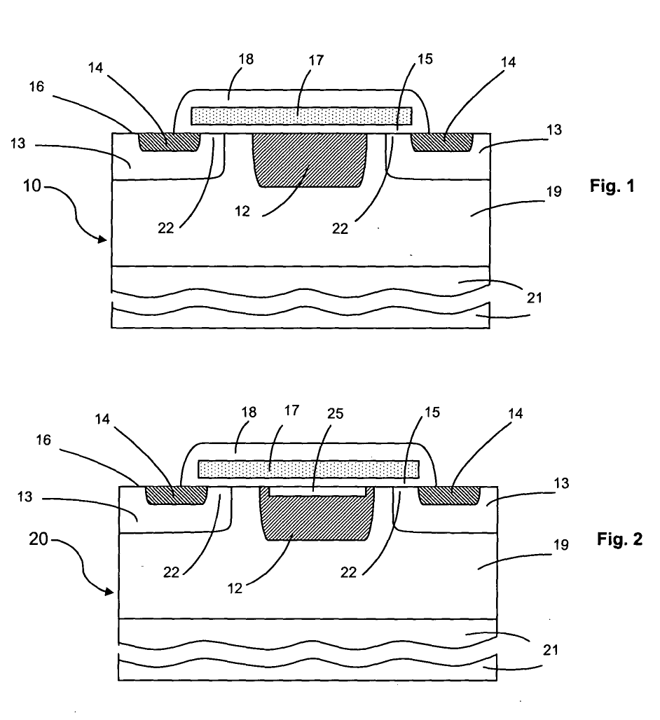

Turning now to the drawings, in which like reference characters indicate corresponding elements having similar functions throughout the several views. The dimensions are not drawn to scale for illustration purposes to accentuate various features of the device. Attention is first directed to FIG. 1 in which is seen the main portion of a power transistor cell, such as metal oxide semiconductor field effect transistor (MOSFET), embodying the principles of the instant invention, generally indicated by the reference character 10 containing semiconductor, conductor and insulator regions which comprise the transistor and enable its function. Regions 15 and 18 are gate insulators and region 17 is a conductor, while the remaining regions in FIG. 1 are semiconductor materials. The transistor is also comprised of source region 14 at semiconductor surface 16; body region 13 adjacent source 14; gate conductor 17 surrounded by first gate insulator 15 and third gate insulator 18, which overlay body 13 and overlap source 14 at semiconductor surface 16, channel region 22, and portion of epitaxial layer 19; and substrate 21. A portion of the drain region adjacent gate generally referred to as gate-to-drain region is the subject for several treatments in the present invention. The epitaxial layer 19 between the edge of the body region 13 and substrate interface, referred as the drift region of the device, is a portion of the drain region. Semiconductor materials have two possible polarities, either n-type or p-type, also referred to them as conductivity types. In a preferred embodiment body region 13 has first polarity, while all other semiconductor regions have second polarity, which is opposite to said first polarity. Regions with said second polarity preferably have controllable carrier concentrations. Isolated metal contacts, not shown, to source, gate, and drain, preferably at the substrate, complete a vertical embodiment of the device whereby current flows between drain and source. Typically a high density of cells is paralleled monolithically to enable conduction of large current and power.

As further seen in FIG. 1, and as a preferred embodiment of this invention, transistor construction further comprises region 12, which is added to enhance current conductance and reduce on-resistance of the transistor. Region 12 is formed with said second polarity and carrier, also referred to as impurity, concentration greater than the carrier concentration of epitaxial layer 19. In an alternate embodiment of the instant invention carrier concentration of region 12 is greater than the carrier concentration of body region 13. Region 12 may be spaced from, or extended to, the body region 13 in this invention and is referred to as a common conduction region.

A further embodiment of the instant invention, indicated by the reference character 20, shown in FIG. 2 teaches the use of a second gate insulator, region 25, at the gate-to-drain adjacent first gate insulator 15 and semiconductor surface 16. In a preferred embodiment of the invention said second gate insulator region 25 may be thicker than first gate insulator, and formed in conjunction with, and at the surface of, the common conduction region 12. In an alternate embodiment of the instant invention a recess is formed at the semiconductor surface wherein said second gate insulator is disposed adjacent said first gate insulator. Thick gate insulator established by the sum of first and second gate insulators enables low gate-to-drain capacitance, and thus faster switching speed of the transistor. Selectively increasing the thickness at the central region by adding region 25 provides low gate-to-drain capacitance, while leaving first gate insulator 15 adjacent the channel to remain thin, thereby enabling low threshold voltage and is a chief object of the instant invention. The increased thickness of a portion of gate insulator is preferably achieved by recessing the surface, or by use of enhanced insulator growth associated with the high carrier concentration of region 12. With enhanced conduction, due to low resistance common conduction region; and switching, due to low gate-to-drain capacitance, the instant invention is advantageous for power MOSFET transistors.

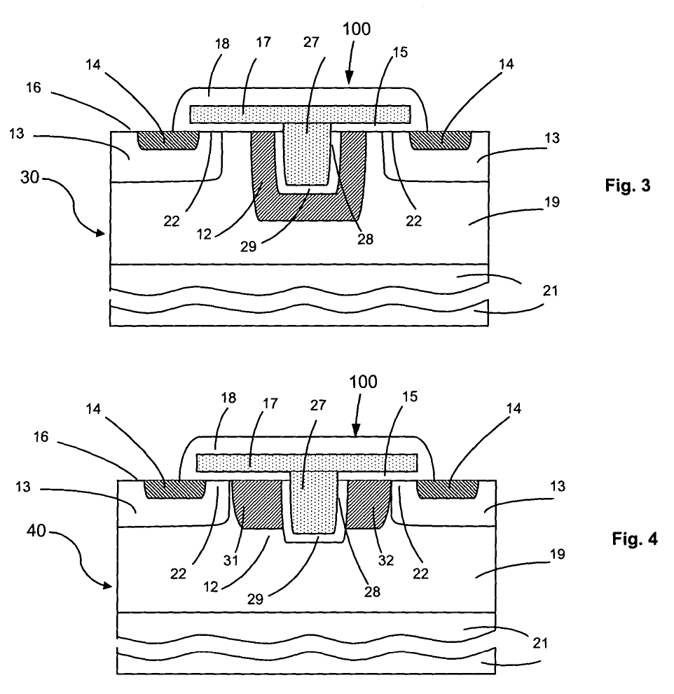

An alternate preferred embodiment is shown in FIG. 3 in which is seen the main portion of a semiconductor MOSFET, embodying the principles of the instant invention, generally indicated by the reference character 30. The transistor is comprised of a substrate 21, epitaxial layer 19, and source region 14 at surface 16. As a chief object of this invention, a gate structure, generally indicated by the reference character 100, is formed in the device including a T-shaped gate conductor region with horizontal element 17 and vertical element 27. The gate conductor is surrounded by insulators 15, 28, 29, and 18. The vertical element of the gate is formed in a groove, or trench, in epitaxial layer 19. The trench is lined with sidewall insulator 28 and bottom insulator 29, which fully isolate the gate conductor from epitaxy layer 19, or drain; region 12; body 13; and source 14. The isolated trench of the gate structure may also be surrounded by common conduction region 12 with said second polarity and high impurity concentration. The present gate structure comprising gate conductor material having large cross-sectional area and volume, enables significant reduction of gate resistance. The thickness of gate insulator region 28 and 29 is preferably made larger than that of region 15, to ensure reduced gate-to-drain capacitance.

FIG. 4 shows a preferred embodiment of the instant invention, generally indicated by the reference character 40, where the device construction is similar to that of FIG. 3 and has the same gate structure 100. Conduction regions 31 and 32 of FIG. 4 are formed shallower than the gate groove, and they are spaced from the body region 13. Other embodiments also include laterally extending regions 31 and 32 all the way to the body region.

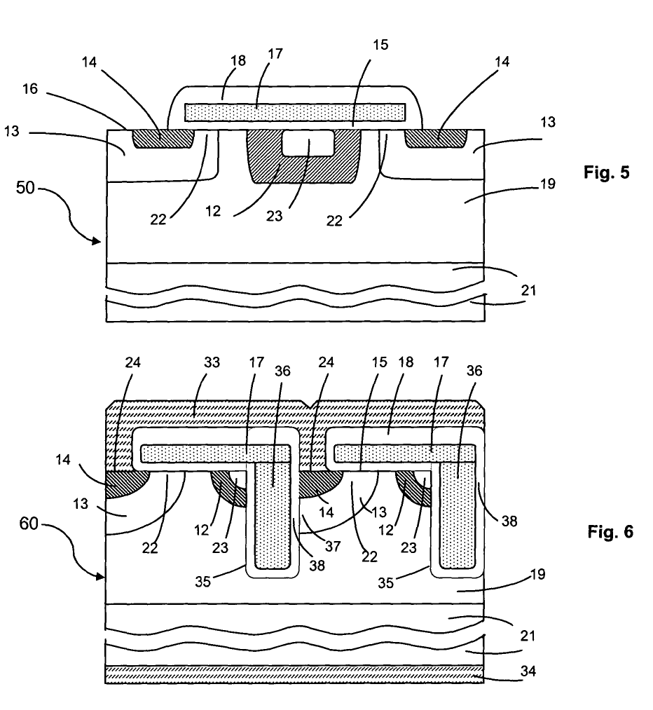

A further embodiment of the invention is illustrated in FIG. 5, which is an extension of FIG. 1, generally indicated by the reference character 50. To further enhance the breakdown voltage performance of the device region 23 having said first polarity is disposed inside region 12. Additional electric field is established between regions 23 and 12 with opposite polarity, which increases the total breakdown voltage that can be sustained by this device.

Yet another embodiment of the instant invention, indicated by the reference character 60, shown in FIG. 6, teaches the use of a planar-trench structure in addition to the improvements obtained by devices illustrated in FIG. 1 and FIG. 5. Two unit cells are shown in FIG. 6 where trench, or groove, region 35 is formed in epitaxial layer 19 and lined with gate insulator 38 and filled with gate conductor 36, preferably polysislicon. The gate structure also includes lateral polysilicon region 17 adjacent vertical element 36 and planar gate insulators 15 and 18. The body region 13 provides lateral channel 22 and vertical channel 37. Regions 12 and 23 disposed in the drain enhance the on-resistance and breakdown voltage, respectively. In a preferred embodiment, regions 12 and 23 are formed in the drain region at the upper outside corner of the trench in epitaxial layer 19. Source region 14 is common to the lateral and vertical channels and is joined at opening 24 to the source top metal 33. Drain metal 34 adjacent substrate 21 completes the device construction.

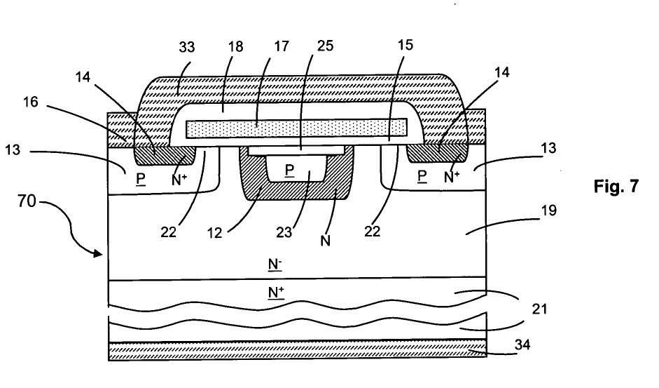

Combinations of various features and embodiments of the present invention will become apparent to those skilled in the art. An example of further embodiments of the instant invention enabled by combining elements of the aforementioned structures is shown in FIG. 7, indicated by the reference character 70. In FIG. 7 a thicker second gate insulator region 25 at the central portion of first gate insulator region 15 described in FIG. 2 is combined with regions 12 and 23 described in FIG. 5. This embodiment provides both thick gate insulator and breakdown voltage improvement. The polarity of the main device regions is indicated by symbols N for n-type or P for p-type with (+) superscript generally indicating high carrier concentration, (−) superscript for low carrier concentration and no superscript for intermediate carrier concentration. The polarity of the device regions used in FIG. 7 represents an n-channel FET, and as it will be apparent to those with ordinary skill in the art, the advantages of this invention can be realized for p-channel devices by using the opposite polarity of the device semiconductor regions.

The above-described embodiments of the invention have uses in semiconductor transistors. For example, region 12 with low resistance can be used in power MOSFETs to reduce the on-resistance, conduction loss, and heat dissipation. Current of a planar transistor flows from the drain region 21 vertically through epitaxy region 19, through the common conduction region 12, laterally through channel 22, into source region 14, and then into source contact top metal 33. Current flow is enabled and controlled by application of gate voltage to gate conductor 17. For high cell density current constriction occurs due to close proximity of body regions 13 to each other and low carrier concentration of epitaxial layer. Formation of common conduction region 12 in this invention with higher carrier concentration reduces the current flow constriction, providing a transistor with reduced on-resistance. Furthermore, gate structure 100 with large gate conductor cross sectional area, and thus volume, and thick sidewall insulator 28 and bottom insulator 29, enables low gate resistance and capacitance, significantly increasing the speed of the device and reducing its switching losses. With enhanced switching speed, enabled by low gate resistance and gate to drain capacitance; and conduction, due to low resistance of common conduction region, the instant invention provides advantages to power MOSFET transistors for high frequency power conversion applications.

What is claimed is:

1. A semiconductor device, comprising:
a body region of a first polarity;
an epitaxial layer of a second polarity having a top surface where said body region is formed extending downwardly from said top surface;
a substrate of said second polarity atop which said epitaxial layer is formed;
a source region of said second polarity formed within said body region;
a drain region of said second polarity, comprising a portion of said epitaxil layer outside body region and extending downward to said substrate;
a channel region provided in said body region at said top surface outlined by the junction between said body and drain regions, and the junction between said body and said source regions;
a first gate insulator, or dielectric layer, adjacent said channel, overlying a first gate-to-drain region, and overlapping a portion of said source region at said top surface; and
a first drain enhancement region of said second polarity is disposed at said first gate-to-drain region in said epitaxial layer, extending downwardly from said top surface.

2. The semiconductor device of claim 1, wherein said first drain enhancement region is formed with carrier concentration greater than the carrier concentration of said body region.

3. The semiconductor device of claim 1, wherein said first drain enhancement region is formed with carrier concentration greater than that of said epitaxial layer, which comprises said first portion of said drain region.

4. The semiconductor device of claim 1, wherein said first drain enhancement region is spaced from said body region.

5. The semiconductor device of claim 1, wherein said first drain enhancement region is extended to said body region.

6. The semiconductor device of claim 1, further comprising a second gate insulator formed at said first gate-to-drain region and adjacent said first gate insulator.

7. The semiconductor device of claim 6, wherein said second gate insulator is spaced from said body region.

8. The semiconductor device of claim 6, wherein the total thickness of insulating material consisting of said first and said second gate insulators at said first gate-to-drain region is greater than the thickness of said first gate insulator overlying said channel region.

9. The semiconductor device of claim 6, wherein the thickness of gate insulator overlapping said portion of said source region is greater than the thickness of gate insulator overlying said channel region.

10. The semiconductor device of claim 6, further comprising a second top surface wherein said second top surface is recessed at said first gate-to-drain region wherein said second gate insulator is disposed adjacent said first gate insulator and said second top surfaces.

11. The semiconductor device of claim 6, wherein said second gate insulator is composed of silicon dioxide, silicon nitride, and the like.

12. A semiconductor device, comprising:
a body region of a first polarity;
an epitaxial layer of a second polarity having a top surface where said body region is formed extending downwardly from said top surface;
a substrate of said second polarity atop which said epitaxial layer is formed;
a source region of said second polarity formed within said body region;
a drain region of said second polarity, comprising a portion of said epitaxial layer outside body region and extending downwardly to said substrate;
a channel region provided in said body region at said top surface outlined by the junction between said body and drain regions, and the junction between said body and said source regions;
a first gate insulator, or dielectric layer, adjacent said channel, overlying a second gate-to-drain region, and overlapping a portion of said source region at said top surface;
a first drain enhancement region of said second polarity is disposed in drain region in said epitaxial layer at said second gate-to-drain region; and
a gate enhancement structure is formed at said second gate-to-drain region having a gate conductor consisting of a lateral and a vertical elements and enclosed by insulators.

13. The semiconductor device with gate enhancement structure of claim 12; wherein said second gate-to-drain region comprises a gate trench formed in said first portion of said drain region, wherein said vertical element is formed into said gate trench.

14. The semiconductor device with gate enhancement structure of claim 12; wherein said vertical element in said gate trench is disposed within said first drain enhancement region.

15. The semiconductor device with gate enhancement structure of claim 12; wherein said vertical element in said gate trench is disposed within said first drain enhancement region is isolated by gate insulator, or dielectric layer, at bottom side and sidewalls from said first drain enhancement region.

16. The semiconductor device with gate enhancement structure of claim 13; wherein said vertical element is deeper than said first drain enhancement region.

17. The semiconductor device with gate enhancement structure of claim 13; wherein said gate trench is deeper than said first drain enhancement region.

18. The semiconductor device with gate enhancement structure of claim 13; wherein said first drain enhancement region is extended to said body region.

19. A semiconductor device, comprising:
a body region of a first polarity;
an epitaxial layer of a second polarity having a top surface where said body region is formed extending downwardly from said top surface;
a substrate of said second polarity atop which said epitaxial layer is formed;
a source region of said second polarity formed within said body region;
a drain region of said second polarity, comprising a portion of said epitaxial layer outside body region and extending downwardly to said substrate;
a channel region provided in said body region at said top surface outlined by the junction between said body and drain regions, and the junction between said body and said source regions;
a first gate insulator, or dielectric layer, adjacent said channel, overlying a first gate-to-drain region, and overlapping a portion of said source region at said top surface;
a first drain enhancement region of said second polarity is disposed at said first gate-to-drain region in said epitaxial layer, extending downwardly from said top surface; and
a second drain enhancement region of said first polarity is formed within said first drain enhancement region.

20. The semiconductor device of claim 19, wherein the carrier concentration or doping level, of said second drain enhancement region is greater than that of said first drain enhancement region.

21. The semiconductor device of claim 19, wherein the depth of said second drain enhancement region is greater than that of said first drain enhancement region.

22. The semiconductor device of claim 19, wherein the width of said second drain enhancement region is spaced from said body region.

23. The semiconductor device of claim 19, wherein the width of said second drain enhancement region is smaller than that of said first drain enhancement.

24. A semiconductor device of claim 19, further comprising said second gate insulator is formed adjacent said second and said first drain enhancement regions and adjacent said first gate insulator at said first gate-to-drain region.

25. Semiconductor devices of claims 6 and 24, wherein the thickness of said second gate insulator is different from that of said first gate insulator.

26. A semiconductor device, comprising:
a body region of a first polarity;
an epitaxial layer of a second polarity having a top surface wherein said body region is formed extending downwardly from said top surface;
a substrate of said second polarity atop which said epitaxial layer is formed;
a source region of said second polarity formed within said body region;
a drain region of said second polarity, comprising a portion of said epitaxil layer outside body region and extending downwardly to said substrate;
a first drain enhancement region of said second polarity disposed at third gate-to-drain region in said epitaxial layer;
a second drain enhancement region of said first polarity is formed within said first drain enhancement region; and
a second gate structure further comprising, a lateral gate conductor element for activation of a lateral channel, and a vertical gate conductor element for activation of a vertical channel formed at a sidewall of a second trench, such that one trench sidewall, i.e. one half, is against said body region and said channel region therein, and the second trench sidewall is against said epitaxial layer portion of the drain, wherein a third gate-to-drain region is formed between said drain region and gate structure, wherein said first and second drain enhancement regions are disposed.

27. The semiconductor device of claim 26, wherein said lateral and vertical gate conductor elements are joined.

28. The semiconductor device of claim 26, wherein said lateral and vertical gate conductor elements are spaced.

29. A semiconductor device of claim 26, wherein in each cell each set of a lateral and a vertical channel shares a common source and a common drain.

30. A semiconductor device of claim 26, wherein said common drain region is enhanced with first and second drain enhancement regions at junction, or corner, formed between sidewall and lateral surface in the drain region at said third gate-to-drain region.

31. A method of making a semiconductor device, generally using advanced semiconductor masking and lithography techniques, comprising the following steps:
forming a body region of semiconductor material having a first polarity, preferably by ion implantation of a p-type dopant into an epitaxial layer having a second polarity, herein n-type, formed on a substrate also with said second polarity;
forming a first drain enhancement region in the epitaxial layer outside body region, preferably by ion implantation through a mask opening and diffusion of a dopant having a second polarity;
forming a first gate insulator, or dielectric layer, adjacent a portion of said epitaxial layer and a portion of said body region, preferably by thermal growth or deposition of silicon dioxide, silicon nitride, and the like;
forming a gate conductor atop said first gate insulator having low resistivity, preferably said gate conductor is composed of polysilicon, metal silicide, metal nitride, and the like;
patterning and etching away gate conductor materials from regions where they are desired to be absent;
forming a source region having a second polarity and high carrier concentration, preferably by ion implantation and thermal diffusion of n-type species such as arsenic, phosphorus, and the like;
forming a body region having a first polarity and medium carrier concentration, preferably by ion implantation and thermal diffusion of p-type species such as boron and the like;
depositing a third gate insulator atop, and adjacent sidewalls of said gate conductor, preferably by reduced pressure, or plasma enhanced oxide deposition technique; and
forming source, drain and gate electrodes, preferably by physical deposition of a metal, metal silicide, metal nitride, and the like.

32. A method of claim 31, wherein said first drain enhancement region is formed by high energy ion implantation, preferably 1 to 3 MeV.

33. A method of claim 31, wherein said first drain enhancement region is formed with carrier concentration greater than the carrier concentration of said body region.

34. A method of claim 31, further comprising the steps of forming a second drain enhancement region having a first polarity, preferably by ion implantation.

35. A method of making a semiconductor device, comprising the following steps:
forming a body region of semiconductor material having a first polarity, preferably by ion implantation into an epitaxial layer having a second polarity formed on a substrate also with said second polarity;
forming a second gate insulator at surface of drain region outside body region, preferably by growing or depositing a silicon dioxide, silicon nitride, and the like;
forming a first drain enhancement region in the epitaxial layer outside body region, preferably by ion implantation through a mask opening and diffusion of a dopant having a second polarity;
forming a first gate insulator, or dielectric layer, adjacent said second gate insulator, a portion of said epitaxial layer and a portion of said body region, preferably by thermally growing or depositing silicon dioxide, silicon nitride, and the like; and
completing remaining steps of forming body; source; and source, drain, and gate electrodes, as in claim 31 to complete the semiconductor device fabrication process.

36. A method of making a semiconductor device of claim 35, wherein the semiconductor surface is recessed by etching and wherein said second gate insulator is formed.

37. A method of making a semiconductor device of claim 35, wherein said second gate insulator is formed using local oxidation of silicon, known as LOCOS; wherein silicon nitride is formed firstly, patterned, and then thick oxide layer is formed in the nitride void to provide said second gate insulator; and then said nitride is selectively etched away; or
the reverse process whereby silicon oxide is formed firstly.

38. A method of making a semiconductor device, comprising the following steps:
forming a body region of semiconductor material having a first polarity, preferably by ion implantation into an epitaxial layer having a second polarity formed on a substrate also with said second polarity;
forming a first drain enhancement region in the epitaxial layer outside body region, preferably by ion implantation through a mask opening and diffusion of a dopant having a second polarity;
forming a first gate insulator, or dielectric material, adjacent a portion of said epitaxial layer and a portion of said body region, preferably by thermally growing or depositing silicon dioxide, silicon nitride, and the like;
forming a gate structure by etching a trench, or a groove, in drain region outside body region, lining said trench with insulator, filling trench with a vertical element of gate electrode, forming a lateral element of gate electrode, preferably said vertical and lateral gate electrodes are composed of polysilicon having low resistivity, and or polysilicon silicide, and depositing said third gate insulator atop said lateral gate electrode; and
completing remaining steps of forming body; source; and source, drain, and gate electrodes, as in claim 31 to complete the semiconductor device fabrication process.
